(19) United States
(12) Patent Application Publication
(10) Pub. No.: US 2026/0045186 A1
(43) Pub. Date: Feb. 12, 2026

(54) METHOD OF DETECTING DISPLAY PANEL DEFECT, DISPLAY DEVICE, AND ELECTRONIC APPARATUS INCLUDING DISPLAY DEVICE

(71) Applicant: Samsung Display Co., Ltd., Yongin-si (KR)

(72) Inventors: SOOYEON KIM, Yongin-si (KR); JONG JAE LEE, Yongin-si (KR); YONG-SIK HWANG, Yongin-si (KR)

(21) Appl. No.: 19/261,809

(22) Filed: Jul. 7, 2025

(30) Foreign Application Priority Data
Aug. 9, 2024 (KR) 10-2024-0107102

(51) Int. Cl. G09G 3/00; G09G 3/3233

(52) U.S. Cl. CPC G09G 3/006; G09G 3/3233; G09G 2300/0413; G09G 2300/0842; G09G 2330/10; G09G 2330/12

(57) ABSTRACT

In a method of detecting a display panel defects, the method includes: applying a voltage to one or more pixels; and measuring a current flowing through a dummy pixel line.

### CROSS-REFERENCE TO RELATED APPLICATION

The present application claims priority to and the benefit Korean Patent Application No. 10-2024-0107102, filed on Aug. 9, 2024, in the Korean Intellectual Property Office, the entire disclosure of which is incorporated herein by reference.

### BACKGROUND

### 1. Field

Aspects of some embodiments of the present disclosure relate to a method of detecting a display panel defect and a display device.

### 2. Description of the Related Art

A display panel or display device contains a plurality of pixels, and when a defect occurs in some of the plurality of pixels, additional damage may occur, such as fire due to a short circuit, or damage to the entire display panel.

Meanwhile, when a defect occurs in some of the plurality of pixels, a pixel repair technology may be used to repair the defective pixels instead of replacing the entire display panel.

The above information disclosed in this Background section is only for enhancement of understanding of the background and therefore the information discussed in this Background section does not necessarily constitute prior art.

### SUMMARY

Aspects of some embodiments of the present disclosure include a method of detecting a display panel defect using a repair line and a display device.

Additional aspects will be set forth in part in the description which follows and, in part, will be apparent from the description, or may be learned by practice of the presented embodiments of the disclosure.

According to some embodiments of the present disclosure, in a method of detecting a display panel defect, the method includes: applying a voltage to one or more pixels and measuring a current flowing through a dummy pixel line.

According to some embodiments, the voltage applied to the one or more pixels may be applied through a data line that is configured to transmit a data signal to the one or more pixels.

According to some embodiments, the voltage applied to the one or more pixels may be generated by a data driver and applied to the data line.

According to some embodiments, the current flowing through the dummy pixel line may be measured by a sensing driver.

According to some embodiments, the sensing driver includes a current detector, and the current flowing through the dummy pixel line is converted into a sensing voltage by the current detector, and the sensing voltage and a reference voltage may be input to a comparator included in the current detector.

According to some embodiments, the method of evaluating a display driving element may further include determining that a defect has occurred when the current is equal to or greater than the reference value.

According to some embodiments, the reference value may be set based on whether pixel repair has been performed.

According to some embodiments of the present disclosure, a display device includes: a display panel including a display area in which an image is displayed and a non-display area outside the display area; a plurality of active pixels arranged in a first direction and a second direction in the display area; a plurality of dummy pixels arranged in the second direction in the non-display area; a plurality of data lines connected to the plurality of active pixels and extending in the second direction; at least one dummy pixel line connected to the plurality of dummy pixels and extending in the second direction; a plurality of repair lines connected to the plurality of dummy pixels and extending in a first direction, each of which is connected to at least one dummy pixel and at least one active pixel; a data driver supplying a data signal to the plurality of data lines; and a sensing driver detecting a sensing signal applied to the at least one dummy pixel line to detect a defect in the display panel.

According to some embodiments, a current flowing through a dummy pixel line may be measured by the sensing driver in response to a voltage applied to the one or more pixels by the data driver.

According to some embodiments, the sensing driver may determine that a defect has occurred when the current is equal to or greater than a reference value.

According to some embodiments, the reference value may be set based on whether pixel repair has been performed.

According to some embodiments, the sensing driver and the data driver may be configured to be integrated.

According to some embodiments, the sensing driver detects a change in the current of the at least one dummy pixel line, and the change in the current may occur when a current path is created between at least one of the plurality of repair lines and one of the plurality of data lines.

According to some embodiments, the sensing driver includes one or more current detectors, and a sensing signal applied to the at least one dummy pixel line is converted into a sensing voltage by the one or more current detectors, and the sensing voltage and a reference voltage may be input to each of one or more comparators included in the one or more current detectors.

Other aspects, features, and characteristics other than those described above will become more apparent from the following drawings, claims and detailed description of the present disclosure.

These general and specific aspects may be implemented using any system, method, computer program, or combination of any systems, methods, and computer programs.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a block diagram schematically illustrating a display device according to some embodiments;

FIG. 2 is a block diagram illustrating a pixel repair process according to some embodiments;

FIG. 3 is a block diagram to further explain a pixel repair process according to some embodiments;

FIG. 4 is a block diagram illustrating a process for detecting a display panel defect according to some embodiments of the present disclosure;

FIG. 5 is a block diagram illustrating a current path according to a defect according to some embodiments of the present disclosure;

FIG. 6 is a block diagram to further explain a process for detecting a display panel defect according to some embodiments of the present disclosure;

FIG. 7 is a block diagram illustrating a sensing driver according to some embodiments of the present disclosure;

FIG. 8 is a circuit diagram illustrating a current detector according to some embodiments of the present disclosure;

FIG. 9 is a block diagram illustrating the implementation of a sensing driver when a plurality of dummy areas are arranged according to some embodiments of the present disclosure; and

FIG. 10 is a flow diagram illustrating a method of detecting a display panel defect according to some embodiments of the present disclosure.

FIG. 11 is a block diagram showing an electronic apparatus according to some embodiments of the present disclosure.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The present disclosure may undergo various modifications and have various embodiments, and specific embodiments are illustrated in the drawings and described in detail in the detailed description. The effects and features of the present disclosure and the method of achieving them may become clear with reference to the embodiments described in detail below together with the drawings. However, embodiments according to the present disclosure are not limited to the embodiments disclosed below and may be implemented in various forms.

In the embodiments below, the terms first, second, or the like are not used in a limiting sense but are used for the purpose of distinguishing one component from another.

In the embodiments below, singular expressions may include plural expressions unless the context clearly indicates otherwise.

In the embodiments below, terms such as comprise, include, and/or may have mean that a feature or component described in the specification is present, and do not preclude in advance the possibility that one or more other features or components may be added.

In the embodiments below, when it is said that a part of such as a unit, area, component, or the like is located above or on another part, it may include not only the case where it is directly above the other part, but also the case where another unit, area, component, or the like is interposed between them.

In the embodiments below, terms such as connect, combine, or the like do not necessarily imply a direct and/or fixed connection or combination of two members, unless the context clearly indicates otherwise, and do not preclude the presence of another member between the two members.

In the drawings, components may be exaggerated or reduced in size for convenience of explanation. For example, the size and/or thickness of each component shown in the drawings are arbitrarily shown for convenience of explanation, and therefore embodiments according to the present disclosure are not necessarily limited to what is shown.

Hereinafter, aspects of some embodiments of the present disclosure will be described in more detail with reference to the attached drawings. When describing with reference to the drawings, identical or corresponding components are given the same drawing reference numerals and redundant descriptions thereof will be omitted.

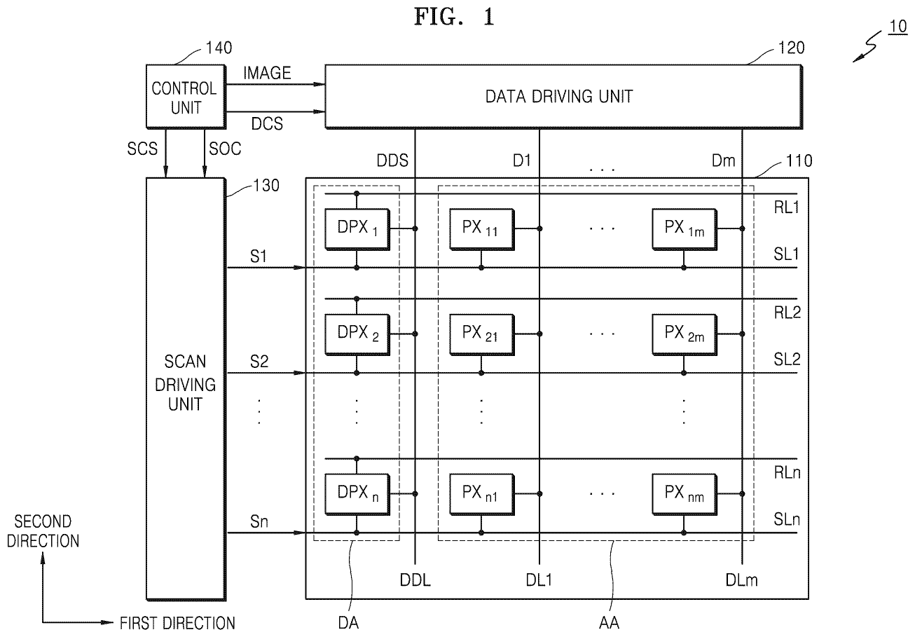

FIG. 1 is a block diagram schematically illustrating aspects of a display device according to some embodiments.

Referring to FIG. 1, a display device 10 according to some embodiments of the present disclosure may include a display panel 110, a data driving unit (or data driver) 120, a scan driving unit (or scan driver) 130, and a control unit (or controller) 140.

The display panel 110 may be a flat display panel such as an organic light-emitting diode (OLED), a thin-film transistor liquid crystal display (TFT-LCD), a plasma display panel (PDP), or a light-emitting diode (LED) display, but embodiments according to the present disclosure are not limited thereto.

The display panel 110 may include a display area and a non-display area.

The display area may be defined as an area on the display panel 110 where images to be displayed are displayed, and the non-display area may be defined as an area on the display panel 110 excluding the display area where the images to be displayed are not displayed. According to some embodiments the non-display area may be an area that surrounds (e.g., in a periphery, or outside a footprint of) the display area.

The display panel 110 may include an active area AA in which a plurality of active pixels PX₁₁-PXₙₘ are arranged and a dummy area DA in which a plurality of dummy pixels DPX₁-DPXₙ are arranged. The active area AA may be included in the display area, and the dummy area DA may be included in the non-display area.

According to some embodiments, the dummy area DA may be positioned adjacent to the active area AA. According to some embodiments, the dummy area DA may be positioned on the left or right side of the active area AA or may be positioned on both the left and right sides of the active area AA. However, embodiments according to the present disclosure are not limited thereto, and the dummy area DA may be placed above and/or below the active area AA.

An active area AA of the display panel 110 may include a plurality of scan lines SL1-SLn extending in a first direction (e.g. a horizontal direction) and configured to transmit scan signals S1-Sn to a plurality of active pixels PX₁₁-PXₙₘ of the display panel 110, and a plurality of data lines DL1-DLm extending in a second direction (e.g. a vertical direction) and configured to transmit data signals D1-Dm to a plurality of active pixels PX₁₁-PXₙₘ. The plurality of active pixels PX₁₁-PXₙₘ may be arranged in the first direction and the second direction along the plurality of scan lines SL1-SLn and the data lines DL1-DLm.

According to some embodiments of the present disclosure, the plurality of active pixels PX₁₁-PXₙₘ may be releasably connected to a plurality of data lines.

Additionally, the plurality of active pixels PX₁₁-PXₙₘ may be detachably connected to the plurality of scan lines.

The display panel 110 may include a plurality of repair lines RL1-RLn extending in the first direction. The plurality of repair lines RL1-RLn may be arranged to be connected to a plurality of dummy pixelsDPX₁-DPXₙ and connectable to the plurality of active pixels PX₁₁-PX_{nm.}

A dummy area DA of the display panel 110 may include a plurality of dummy pixels DPX₁-DPXₙ connected to a plurality of scan lines SL1-SLn extending in a first direction and a dummy data line DDL (or a dummy pixel line) extending in a second direction. The plurality of dummy pixels DPX₁-DPXₙ may be arranged along the second direction. However, embodiments according to the present disclosure are not limited thereto, and the plurality of dummy pixels DPX₁-DPXₙ may be arranged along the first direction.

In this specification, for example, “unit pixel” is used to mean one dot of a color close to a natural color, and an active pixel is used to mean one of two or more sub-pixels that constitute “unit pixels” and each of which displays one color. However, embodiments according to the present disclosure are not limited thereto, and the active pixel may also be interpreted to mean one unit pixel including a plurality of sub-pixels. That is, even if it is described in this specification that one active pixel is arranged or connected to another configuration, this may be interpreted as one sub-pixel being arranged or connected to another configuration, or as a plurality of sub-pixels constituting one unit pixel being arranged and connected to another configuration. The same goes for dummy pixels. For example, even if it is described that one dummy pixel is arranged or connected to another configuration, this may be interpreted as one dummy pixel circuit being arranged or connected to another configuration, or as many dummy pixel circuits as the number of sub-pixels constituting one unit pixel being arranged or connected to another configuration. When the presence of one dummy pixel is interpreted as the presence of a plurality of dummy pixel DPX₁-DPXₙ circuits, then the dummy data line DDL connected to the dummy pixel should also be interpreted as including a plurality of dummy data lines DDL each connected to a plurality of dummy pixel DPX₁-DPXₙ circuits.

In this specification, the term “connectable” or “connectably” may mean a state in which connection may be made using a laser or the like in a repair process.

For example, the fact that a first and a second member are arranged to be connectable means that the first and second members are not actually connected but are in a state where they may be connected to each other during the repair process. From a structural point of view, the first and second members that are “connectable” to each other may be arranged to intersect each other in an overlapping area with an insulating film between them. According to the repair process, when the laser is irradiated to the overlapping area, the insulating film within the overlapping area is destroyed, so that the first member and the second member may be electrically connected to each other.

Additionally, in this specification, the term “separable” or “separably” may mean a state in which it may be separated using a laser or the like in the repair process. For example, the fact that the first and second members are detachably connected means that the first and second members are actually connected but are in a state where they may be separated during the repair process. From a structural point of view, the first and second detachably connected members may be arranged to be connected to each other through a conductive connecting member. According to the repair process, when a laser is irradiated on a conductive connecting member, the conductive connecting member is cut as the portion irradiated with the laser melts, and the first member and the second member are electrically insulated from each other.

For example, the conductive connecting member may include a silicon layer that may be melted by a laser. In another example, a conductive connecting member may be severed by melting due to Joule heat generated by a current.

The data driving unit 120 may receive an image signal IMAGE and a data control signal DCS from the control unit 140 and supply data signals to a plurality of data lines D1-Dm and/or a plurality of dummy data lines DDL. According to some embodiments, the data driving unit 120 may include a latch circuit and a level shifter circuit. The latch circuit may store image data received serially and store the data to apply the image data in parallel to the display panel 110, and the level shifter circuit may adjust the level of the actual voltage provided to the display panel 110 corresponding to the image signal IMAGE. Because the specific configuration of the latch circuit and the level shifter circuit may be easily understood by those skilled in the art to which the present disclosure pertains, some detailed description thereof may be omitted.

The scan driving unit 130 may receive a scan control signal SCS provided from the control unit 140 and sequentially apply a plurality of scan signals to a plurality of scan lines. The plurality of scan signals perform a switching function so that the dummy data signals and the plurality of data signals applied through the dummy data line DDL and the plurality of data lines DL1-DLm may be applied to the plurality of dummy pixels DPX₁-DPXₙ and the plurality of active pixels PX₁₁-PX_{nm.}

As illustrated in FIG. 1, the data driving unit 120, the scan driving unit 130, and the display panel 110 are illustrated as separate functional blocks, but embodiments according to the present disclosure are not limited thereto, and the data driving unit 120 and the scan driving unit 130 of the present disclosure may be IC chips mounted on at least a portion of the display panel 110, and may also be driving circuits directly formed on at least a portion of the display panel 110.

The control unit 140 may output a data control signal DCS, a scan control signal SCS, and a scan driving signal SOC to drive the data driving unit 120 and the scan driving unit 130 in synchronization with the image signal IMAGE. The image signal IMAGE may be a signal corresponding to image data applied from an external device and regarding a grayscale value of each active pixel according to the arrangement structure of a plurality of active pixels PX₁₁-PXₙₘ of the display panel 110. In addition, the control unit 140 may additionally modulate or compensate for an external image signal according to the user's preference and the characteristics of the display device 10 and process it into an image signal.

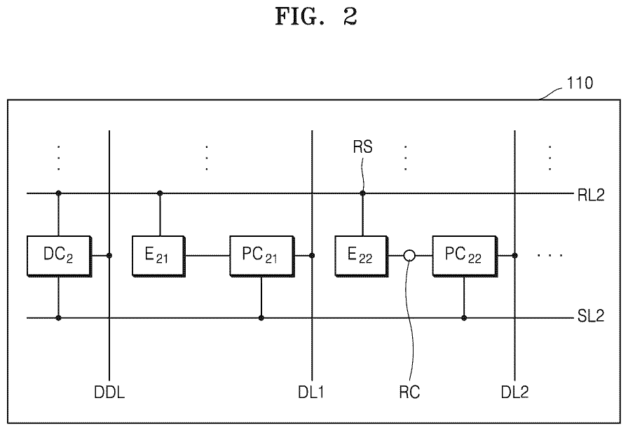

FIG. 2 is a block diagram illustrating a pixel repair process according to some embodiments.

FIG. 2 may be understood as a more detailed illustration of the display panel 110 illustrated in FIG. 1.

According to some embodiments, it may be understood that each of the plurality of active pixels PX₁₁-PXₙₘ includes pixel circuits PC₁₁-PCₙₘ and light-emitting elements E₁₁-Eₙₘ that receive a driving current from the pixel circuits PC₁₁-PCₙₘ and emit light. The light-emitting elements and pixel circuits included in the active pixels may be detachably connected to each other.

The pixel circuits PC₁₁-PCₙₘ may include one or more thin film transistors and capacitors. The plurality of active pixels PX11-PXnm emit light of one color, for example, one of red, blue, green, and white. However, embodiments according to the present disclosure are not limited thereto, and may emit light of other colors besides red, blue, green, and white. The pixel circuits PC₁₁-PCₙₘ may be connected to a scan line of the same row among a plurality of scan lines SL1-SLn and may be connected to a data line of the same column among a plurality of data lines DL1-DLm.

Meanwhile, each of the plurality of dummy pixels DPX₁-DPXₙ may include a dummy pixel circuit DC₁-DCₙ. Each of the plurality of dummy pixels DPX₁-DPXₙ may or may not include a light-emitting element E11-Enm. According to some embodiments, each of the plurality of dummy pixels DPX₁-DPXₙ is described as not including a light-emitting element E₁₁-Eₙₘ. Each of the dummy pixel circuits DC₁-DCₙ may be configured identically to the pixel circuits of the active pixels PC₁₁-PCₙₘ.

Referring to FIG. 2, dummy pixels and a plurality of active pixels arranged in the second row of the display panel 110 are illustrated. Specifically, referring to FIG. 2, a dummy pixel circuit DC₂, pixel circuits PC₂₁-PC₂ₙ and light-emitting elements E₂₁-E₂ₙ arranged in the second row of the display panel 110 are illustrated.

When a specific active pixel PX is defective, a light-emitting element E and a pixel circuit PC included in the specific active pixel PX may be separated from each other according to the pixel repair process. The light-emitting element E separated from the pixel circuit PC may be connected to a repair line according to the pixel repair process. By being connected to the repair line, the light-emitting element E may be connected to a dummy pixel DPX (or a dummy pixel circuit DC) corresponding thereto.

In the example of FIG. 2, the pixel repair process will be explained assuming that an active pixel PX₂₂ corresponding to the area where the second scan line SL2 and the second data line DL2 intersect is defective.

When the active pixel PX₂₂ is defective, a repair cut RC may be formed in a portion of the connection wire connecting a light-emitting element E₂₂ of the active pixel PX₂₂ and a pixel circuit PC₂₂ for pixel repair. Through the repair cut RC, the light-emitting element E₂₂ and the pixel circuit PC₂₂ may be separated from each other.

Meanwhile, the light-emitting element E₂₂ may be connected to a second repair line RL2 through a repair short RS. In this way, the light-emitting element E₂₂ of the defective active pixel PX₂₂ may be connected to the dummy pixel circuit DC₂.

The data driving unit 120 may apply a second data signal D2 applied to the second data line DL2 as a dummy data signal DDS applied to a dummy data line DDL at the time when the second scan signal S2 is applied to the second scan line SL2, and accordingly, the second dummy pixel circuit DC₂ may provide a current corresponding to the second data signal D2 applied to the defective active pixel PX₂₂ to an OLED of a light-emitting element E12 of the defective pixel through the second repair line RL2 and the repair short RS.

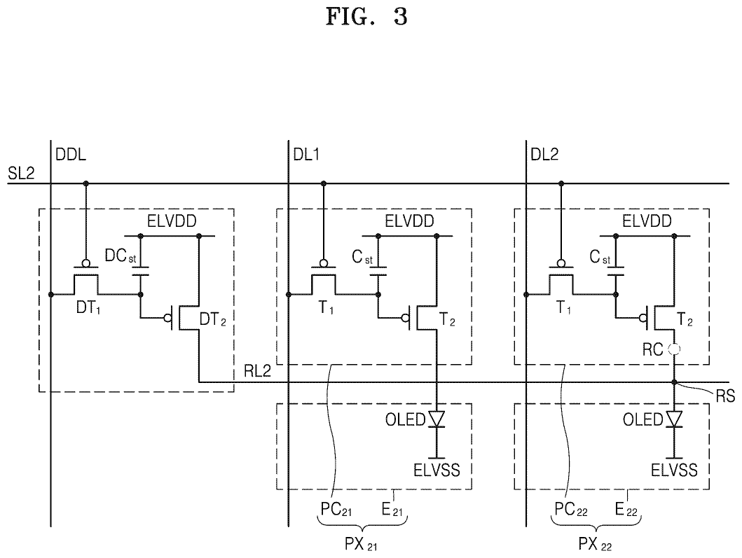

FIG. 3 is a block diagram to further explain a pixel repair process according to some embodiments.

FIG. 3 may be understood as a more detailed illustration of the pixels illustrated in FIG. 2. Referring to FIG. 3, a dummy pixel DPX₂, an active pixel PX₂₁, and the active pixel PX₂₂ are illustrated in more detail.

Referring to FIG. 3, a light-emitting element E may be an organic light-emitting diode OLED including a first electrode, a second electrode opposing the first electrode, and a light-emitting layer between the first electrode and the second electrode. The first electrode and the second electrode may be an anode electrode and a cathode electrode, respectively. A pixel circuit PC may have two transistors T1 and T2 and one capacitor.

A first transistor T1 has a gate electrode connected to a scan line SLi, a first electrode connected to a data line DLi, and a second electrode connected to a gate electrode of a second transistor T2 and a first electrode of a capacitor Cst.

The second transistor T2 has the first electrode that receives a first power supply voltage ELVDD from a first power supply, and a second electrode that is connected to a pixel electrode of the light-emitting element E.

The capacitor Cst has a second electrode that receives the first power supply voltage ELVDD from the first power supply.

The first transistor T1 transmits a data signal D supplied from the data line DLj to the first electrode of the capacitor Cst when a scan signal S is supplied from the scan line SLi. Accordingly, the capacitor Cst is charged with a voltage corresponding to the data signal D, and a driving current corresponding to the voltage charged in the capacitor Cst is transmitted to the light-emitting element E through the second transistor T2, causing the light-emitting element E to emit light.

Referring to FIG. 3, it may be understood that a dummy pixel DPX is configured identically to an active pixel PX except that it does not include a light-emitting element E. That is, a dummy pixel circuit DC of the dummy pixel DPX may also operate in the same manner as the active pixel PX, including two transistors and one capacitor.

Although the active pixel PX illustrated in FIG. 3 is described as including two transistors and one capacitor, this is provided as an example and embodiments according to the present disclosure are not limited thereto. The active pixel PX according to the present disclosure may be formed in any structure.

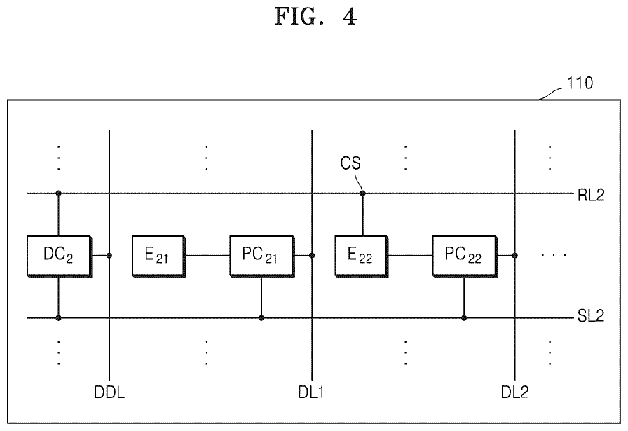

FIG. 4 is a block diagram illustrating a process for detecting a display panel defect according to some embodiments of the present disclosure.

Referring to FIG. 4, like FIG. 2, dummy pixels and a plurality of active pixels arranged in the second row of the display panel 110 are illustrated. Specifically, referring to FIG. 4, a dummy pixel circuit DC2, pixel circuits PC₂₁-PC₂ₙ and light-emitting elements E₂₁-E₂ₙ arranged in the second row of the display panel 110 are illustrated.

A short circuit may occur in the circuit on the display panel 110 due to an external impact to the display panel 110 or the display device 10. Such short circuits may be detected by the process for detecting a display panel defect of the present disclosure.

As described above, a plurality of repair lines RL1-RLn are connected to a plurality of dummy pixels DPX₁-DPXₙ but are arranged so as to be connectable to a plurality of active pixels PX₁₁-PXₙₘ and are not connected to the plurality of active pixels PX₁₁-PXₙₘ under normal circumstances.

However, a short circuit may occur between a specific active pixel PX and a specific repair line RL corresponding thereto due to an external impact or the like. In such a case, a current path may be created between a repair line RL corresponding to the active pixel PX where the short circuit has occurred and a data line DL. Through this current path, a display panel defect may be detected.

Referring to FIG. 4, a defect is shown in an active pixel PX₂₂. Specifically, a circuit short CS may occur between a light-emitting element E₂₂ of the active pixel PX₂₂ and a second repair line RL2 for a specific reason.

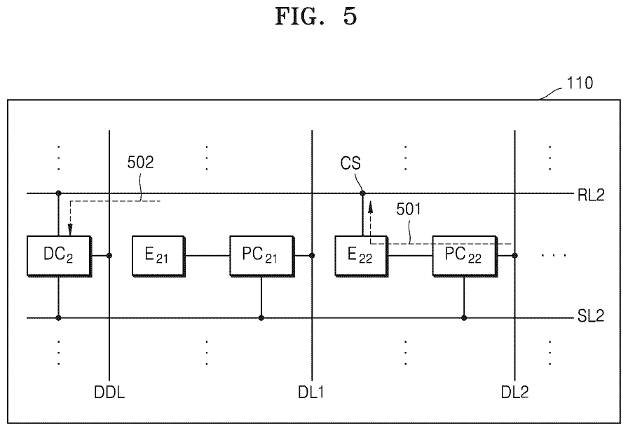

FIG. 5 is a block diagram illustrating a current path according to a defect according to some embodiments of the present disclosure.

Due to the circuit short CS generated by the defect described above with reference to FIG. 4, a current path that did not exist before may be generated between a second data line DL2 and the second repair line RL2.

Referring to FIG. 5, the second data line DL2 and the second repair line RL2 may electrically influence each other through a current path generated by the circuit short CS between the defective active pixel PX₂₂ and the second repair line RL2. For example, a voltage applied through the second data line DL2 may change the current of the second repair line RL2 through a generated first current path 501.

In addition, referring to FIG. 5, the second repair line RL2 is connected to the dummy pixel circuit DC₂, and the dummy pixel circuit DC₂ is connected to the dummy data line DDL, so that the second repair line RL2 and the dummy data line DDL may have an electrical influence on each other. For example, the current of the second repair line RL2 may change the current or voltage inside the dummy pixel circuit DC₂ or the dummy pixel DPX₂ and the current of the dummy data line DDL through a second current path 502.

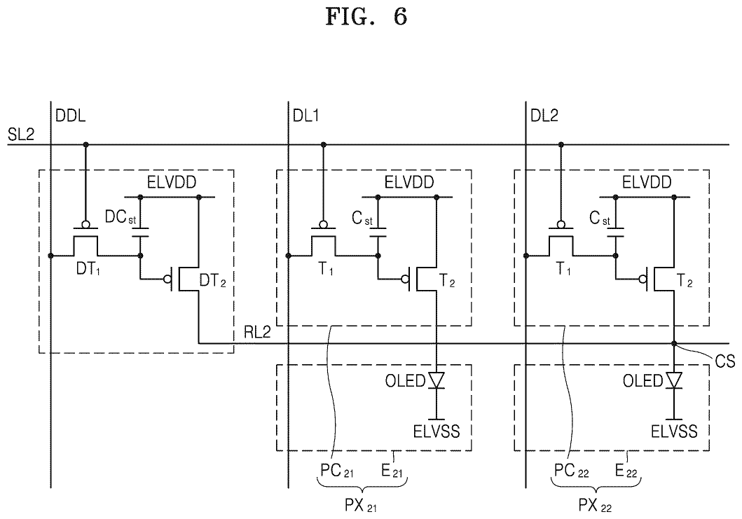

FIG. 6 is a block diagram to further explain a process for detecting a display panel defect according to some embodiments of the present disclosure.

FIG. 6 may be understood as a more detailed illustration of the pixels illustrated in FIGS. 4 and 5.

Referring to FIG. 6, it is illustrated that the circuit short CS described above occurs at a node between the pixel circuit PC₂₂ of the active pixel PX₂₂ and the light-emitting element E₂₂, so that the node between the pixel circuit PC₂₂ and the light-emitting element E₂₂ is connected to the second repair line RL2.

Accordingly, as described above, a voltage applied through the second data line DL2 may change the current of the second repair line RL2, change the current or voltage inside the dummy pixel circuit DC₂, and change the current of the dummy data line DDL through a newly created current path.

Meanwhile, in the examples of FIGS. 4 to 6, a case is described where a circuit short CS occurs between a light-emitting element E of an active pixel PX and a repair line RL, but the embodiments of the present disclosure may be applied even when a circuit short CS occurs in another part. For example, when a circuit short CS occurs between a pixel circuit PC of an active pixel PX and a repair line RL, a process for detecting a display panel defect according to the present disclosure may be performed.

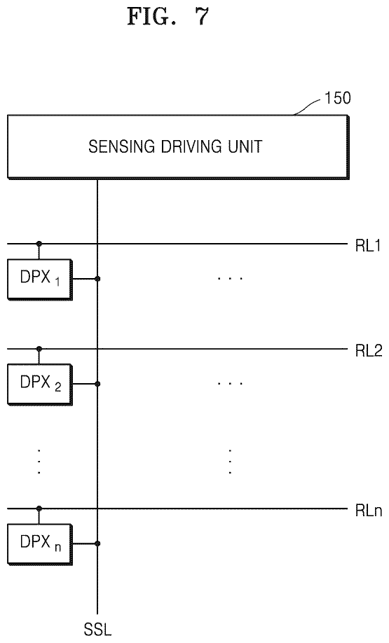

FIG. 7 is a block diagram illustrating aspects of a sensing driving unit (or sensing driver) according to some embodiments of the present disclosure.

According to some embodiments, the display device 10 of the present disclosure may further include a sensing driving unit 150. According to some embodiments, the sensing driving unit 150 may be configured to be integrated with the control unit 140. According to some embodiments, the sensing driving unit 150 may be configured to be integrated with the data driving unit 120.

According to some embodiments, the sensing driving unit 150 may detect a sensing signal SS applied to a sensing line SSL.

According to some embodiments, the sensing line SSL may extend in a second direction and be connected to a plurality of dummy pixels DPX₁-DPXₙ.

However, embodiments according to the present disclosure are not limited thereto, and the sensing line SSL may extend along a first direction when a plurality of dummy pixels DPX₁-DPXₙ are arranged along the first direction.

According to some embodiments, the sensing driving unit 150 may measure the intensity of a sensing signal SS applied to a sensing line SSL from a plurality of dummy pixels DPX₁-DPXₙ. According to some embodiments, the sensing driving unit 150 may detect a change in the sensing signal SS. According to some embodiments, the sensing driving unit 150 may compare the sensing signal SS with a reference value.

According to some embodiments, the sensing driving unit 150 may detect a change in the current of a sensing line SSL according to a change in the current or voltage inside a dummy pixel DPX by measuring a sensing signal SS, thereby detecting a display panel defect.

According to some embodiments, a sensing line SSL may be identical to the dummy data line DDL described above. That is, the sensing driving unit 150 may detect a dummy data signal DDS applied to the dummy data line DDL. The sensing driving unit 150 may measure the intensity of a dummy data signal DDS or detect a change in the current of a dummy data line DDL.

According to some embodiments, for detecting a sensing signal SS of the sensing driving unit 150 for detecting a display panel defect, a voltage may be applied through a plurality of data lines DL1-DLm by the data driving unit 120. According to some embodiments, for detecting a display panel defect, a voltage applied through a plurality of data lines DL1-DLm may be higher than a voltage applied for operation of the display panel 110 or light-emitting of pixels PX.

According to some embodiments, for detecting a display panel defect, any one of a plurality of data lines DL1-DLm may be selected and a voltage applied. Through this, the active pixel PX where the defect occurred may be identified.

Meanwhile, as described above, according to some embodiments, the sensing driving unit 150 may be configured to be integrated with the data driving unit 120. In this case, the sensing driving unit 150 may apply a voltage through a plurality of data lines DL1-DLm to detect a display panel defect and detect a sensing signal SS applied to a sensing line SSL (or a dummy data line DDL).

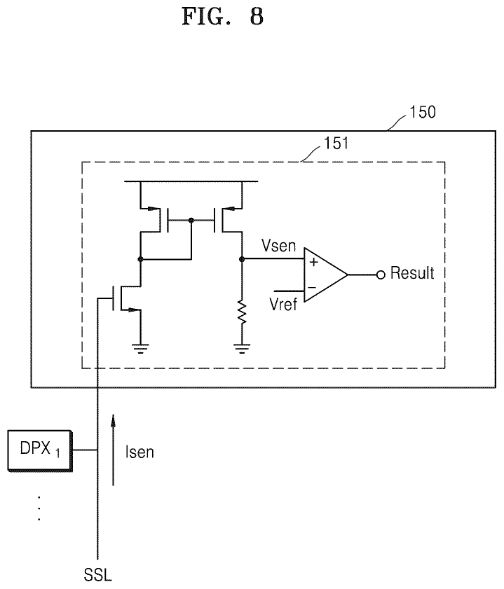

FIG. 8 is a circuit diagram illustrating a current detector according to some embodiments of the present disclosure.

According to some embodiments, the sensing driving unit 150 may include a current detector 151. The current detector 151 may detect a sensing current Isen applied to a sensing line SSL.

Referring to FIG. 8, when a sensing current Isen is applied to the current detector 151, it is converted into a corresponding sensing voltage Vsen by the current detector 151, and the sensing voltage Vsen and a reference voltage Vref may be input to a comparator. Based on an output value of the comparator, it may be determined whether a display panel defect has occurred. Specifically, when the sensing voltage Vsen is less than the reference voltage Vref, it may be determined that a display panel defect has not occurred. Conversely, when the sensing voltage Vsen is higher than the reference voltage Vref, a display defect may be determined to have occurred.

Meanwhile, according to some embodiments, the reference value (or reference voltage) may be set based on whether pixel repair has been performed on the display panel 110. Before a defect occurs, when pixel repair has been performed on the display panel 110, a repair line RL and an active pixel PX are connected through a repair short RS, so a signal of a sensing line SSL (or a dummy data line DDL) may be different from that in a case where pixel repair has not been performed on the display panel 110. Therefore, the reference value set for the display panel 110 on which pixel repair has been performed may be different from the reference value set for the display panel 110 on which pixel repair has not been performed. For example, the reference value set for the display panel 110 on which pixel repair has been performed may be greater than the reference value set for a display panel 110 on which pixel repair has not been performed.

Through this, even if pixel repair of the display panel 110 is performed before shipment, a defect in the display panel 110 that occurs during an actual use of the display device 10 may be detected.

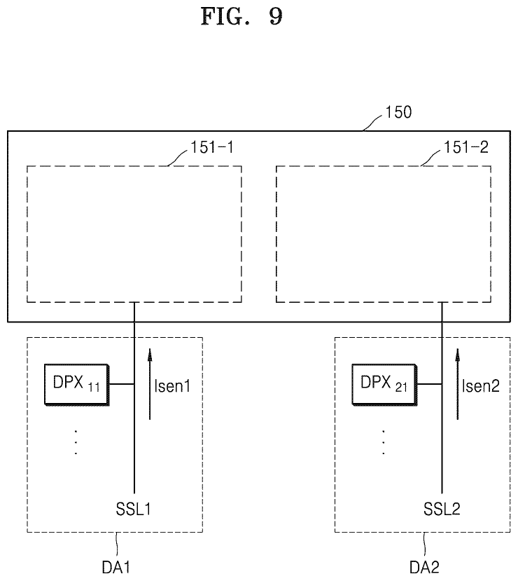

FIG. 9 is a block diagram illustrating the implementation of a sensing driving unit when a plurality of dummy areas are arranged according to some embodiments of the present disclosure.

According to some embodiments, a plurality of dummy areas DA may be arranged on the display panel 110. For example, as described above, the dummy areas DA may be arranged on both the left and right sides of the active area AA.

Referring to FIG. 9, a first dummy area DA1 positioned on the left side of the active area AA and a second dummy area DA2 positioned on the right side of the active area AA are illustrated.

According to some embodiments, when a plurality of dummy areas DA are arranged, the sensing driving unit 150 may include current detectors 151-1 and 151-2 corresponding to each of a plurality of dummy areas DA.

Referring to FIG. 9, the current detector 151-1 may detect a first sensing current Isen1 applied to a first sensing line SSL1 connected to a plurality of dummy pixels DPX₁₁-DPX₁ₙ arranged in the first dummy area DA1, and the current detector 151-2 may detect a second sensing current Isen2 applied to a second sensing line SSL2 connected to a plurality of dummy pixels DPX₂₁-DPX₂ₙ arranged in the second dummy area DA2.

Even when three or more dummy areas DA are arranged on the display panel 110, the embodiments illustrated in FIG. 9 may be applied analogically.

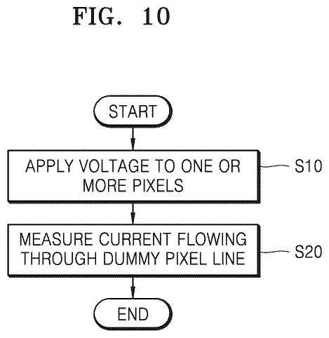

FIG. 10 is a flow diagram illustrating aspects of a method of detecting a display panel defect according to some embodiments of the present disclosure.

Although FIG. 10 illustrates various operations in a method of detecting a display panel defect according to some embodiments, embodiments according to the present disclosure are not limited thereto, and according to various embodiments, the method may include additional operations or fewer operations without departing from the spirit and scope of embodiments according to the present disclosure.

The method of detecting a display panel defect, as shown in FIG. 10, is related to the embodiments described above, so even if the contents are omitted below, the contents described above may also be applied to the method of FIG. 10.

The operations illustrated in FIG. 10 may be performed based on signals generated and supplied through the control unit 140.

Referring to FIG. 10, the method of detecting a display panel defect of the present disclosure may include applying a voltage to one or more pixels (S10).

According to some embodiments, the voltage applied to one or more pixels may be applied through a data line that is configured to transmit a data signal to one or more pixels.

According to some embodiments, the voltage applied to one or more pixels may be generated by a data driving unit and applied to a data line.

Referring to FIG. 10, the method of detecting a display panel defect of the present disclosure may include measuring a current flowing through a dummy pixel line (S20).

According to some embodiments, a current flowing through a dummy pixel line may be measured by a sensing driving unit.

According to some embodiments, the sensing driving unit includes a current detector, and the current flowing through the dummy pixel line is converted into a sensing voltage by the current detector, and the sensing voltage and a reference voltage may be input to a comparator included in the current detector.

According to some embodiments, the method of detecting a display panel defect of the present disclosure may further include determining that a defect has occurred when a current flowing through a dummy pixel line is equal to or greater than a reference value.

According to some embodiments, the reference value may be set based on whether pixel repair has been performed.

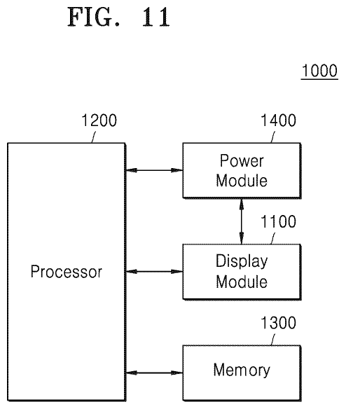

FIG. 11 depicts an electronic apparatus 1000 that includes a display module 1100, a processor 1200, a memory 1300, and a power module 1400. The electronic apparatus 1000 may further include a plurality of ports capable of communicating with a video card, a sound card, a memory card, a USB device, and the like, or communicating with other systems.

The display module 1100 may be the display panel or the display device 10 mentioned above.

The processor 1200 may perform specific calculations or tasks. According to an embodiment, the processor 1200 may be a microprocessor, a central processing unit (CPU), or the like. The processor 1200 may be connected to other components through an address bus, a control bus, a data bus, and the like. According to an embodiment, the processor 1200 may also be connected to an expansion bus such as a peripheral component interconnect (PCI) bus. The processor 1200 may control the display module 1100.

The processor 1200 may control the display module 1100. In an embodiment, the processor 1200 may distribute the image data and the controller signal that are provided to the control unit 17 of FIG. 1 to the display module 1100.

The memory 1300 may store data required for an operation of the electronic apparatus 1000. For example, the memory 1300 may include: a nonvolatile memory device such as an erasable programmable read-only memory (EPROM), an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), or a ferroelectric random access memory (FRAM); and/or a volatile memory device such as a dynamic random access memory (DRAM), a static random access memory (SRAM), or a mobile DRAM.

Each of the embodiments described above may be implemented independently, but the structure of each embodiment may be applied in combination to other embodiments.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

Specific implementations described in the embodiments are examples and do not limit the scope of the embodiments. In addition, if there is no specific mention such as “essential,” “important,” etc., it may not be a necessary component for the application of the disclosure.

The display device and the pixels disclosed herein may be used in various products such as portable electronic devices including mobile phones, smartphones, tablet personal computers (PCs), mobile communication terminals, electronic notebooks, e-books, portable multimedia players (PMPs), navigations, and ultra mobile PCs (UMPCs), and also televisions (TVs), laptops, monitors, billboards, Internet of Things (IoT), or the like. According to an embodiment, the display device and the pixels of this disclosure may also be used in wearable devices such as smart watches, watch phones, glasses-type displays, or head mounted displays (HMDs). According to an embodiment, the display device and pixels of this disclosure may also be used in dashboards of vehicles, center information displays (CIDs) of the center fascia or dashboards of vehicles, mirror displays that replace the side view mirrors of vehicles, and display screens arranged on the rear sides of front seats to serve as entertainment devices for back seat passengers of vehicles.

The embodiments described above may be implemented independently, but may be applied in combination to other embodiments having different structures.

Although the present disclosure has been described with reference to the embodiments shown in the drawings, these are merely examples, and those skilled in the art will understand that various modifications and equivalent other embodiments are possible therefrom. Therefore, the true technical protection scope of the present disclosure should be determined by the technical idea of the appended claims.

The specific implementations described in the embodiments are merely examples and do not limit the scope of the examples in any way. Additionally, if there is no expressions such as “essential,” “importantly,” or the like, it may not be a component absolutely necessary for the application of the present disclosure.

The use of the term “the” and similar referential terms in the specification of embodiments (especially in the claims) may refer to both the singular and the plural. In addition, when a range is described according to some embodiments, it is considered that the invention includes an individual value that falls within the range (unless otherwise stated), and it is the same as describing each individual value that constitutes the range in the detailed description. Lastly, unless the order of the steps constituting the method is clearly stated or stated to the contrary, the steps may be rearranged and performed in an appropriate order and are not necessarily limited to the order of description of the steps. The embodiments are not necessarily limited to the order in which the steps are described. Any use of examples or example terms in the embodiments is merely intended to elaborate the embodiments and is not intended to limit the scope of the embodiments, unless otherwise limited by the claims. Furthermore, those skilled in the art will appreciate that various modifications, combinations and variations may be made according to design conditions and factors within the scope of the appended claims or equivalents thereof.

According to some embodiments of the present disclosure, by utilizing a repair line, a defect may be detected for an entire area of a display panel.

Additionally, because an existing repair line is used, a defect in a display panel may be detected without additional wires or input/output terminals.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A method of detecting a display panel defects, the method comprising:
applying a voltage to one or more pixels; and
measuring a current flowing through a dummy pixel line.

2. The method of detecting a display panel defect of claim 1, wherein
a voltage applied to the one or more pixels is applied through a data line configured to transmit a data signal to the one or more the pixels.

3. The method of detecting a display panel defect of claim 2, wherein
a voltage applied to the one or more pixels is generated by a data driver and applied to the data line.

4. The method of detecting a display panel defect of claim 1, wherein
a current flowing through the dummy pixel line is measured by a sensing driver.

5. The method of detecting a display panel defect of claim 4, wherein
the sensing driver includes a current detector,
a current flowing through the dummy pixel line is converted into a sensing voltage by the current detector, and
the sensing voltage and reference voltage are input to a comparator included in the current detector.

6. The method of detecting a display panel defect of claim 1, further comprising determining that a defect has occurred when the current is equal to or greater than a reference value.

7. The method of detecting a display panel defect of claim 6, wherein
the reference value is set based on whether pixel repair has been performed.

8. A display device, comprising
a display panel including a display area on which an image is displayed and a non-display area outside the display area,
a plurality of active pixels arranged in a first direction and a second direction in the display area,
a plurality of dummy pixels arranged in the second direction in the non-display area,
a plurality of data lines connected to the plurality of active pixels and extending in the second direction,
at least one dummy pixel line connected to the plurality of dummy pixels and extending in the second direction,
a plurality of repair lines connected to the plurality of dummy pixels, extending in a first direction, and each of which is connected to at least one dummy pixel and at least one active pixel,
a data driver configured to supply data signals to the plurality of data lines, and
a sensing driver configured to detect a defect in the display panel by detecting a sensing signal applied to the at least one dummy pixel line.

9. The display device of claim 8, wherein
a current flowing through a dummy pixel line is measured by the sensing driver in response to a voltage applied to the one or more pixels by the data driver.

10. The display device of claim 9, wherein
the sensing driver is configured to determine that a defect has occurred, when the current is equal to or greater than a reference value.

11. The display device of claim 10, wherein
the reference value is set based on whether pixel repair has been performed.

12. The display device of claim 8, wherein
the sensing driver and the data driver are configured to be integrated.

13. The display device of claim 8, wherein
the sensing driver is configured to detect a change in a current of the at least one dummy pixel line, wherein the change in a current is caused by creating a current path between at least one of the plurality of repair lines and one of the plurality of data lines.

14. The display device of claim 8, wherein
the sensing driver includes one or more current detectors,
a sensing signal applied to the at least one dummy pixel line is converted into a sensing voltage by the one or more current detectors, and
a sensing voltage and a reference voltage are input to each of one or more comparators included in the one or more current detectors.

15. An electronic apparatus comprising:
a display device that displays an image; and
a processor that controls the display device,
wherein the display device comprises a display panel including a display area on which an image is displayed and a non-display area outside the display area, a plurality of active pixels arranged in a first direction and a second direction in the display area, a plurality of dummy pixels arranged in the second direction in the non-display area, a plurality of data lines connected to the plurality of active pixels and extending in the second direction, at least one dummy pixel line connected to the plurality of dummy pixels and extending in the second direction, a plurality of repair lines connected to the plurality of dummy pixels, extending in a first direction, and each of which is connected to at least one dummy pixel and at least one active pixel, a data driver configured to supply data signals to the plurality of data lines, and a sensing driver configured to detect a defect in the display panel by detecting a sensing signal applied to the at least one dummy pixel line.

16. The electronic apparatus of claim 15, wherein
a current flowing through a dummy pixel line is measured by the sensing driver in response to a voltage applied to the one or more pixels by the data driver.

17. The electronic apparatus of claim 16, wherein
the sensing driver is configured to determine that a defect has occurred, when the current is equal to or greater than a reference value.

18. The electronic apparatus of claim 17, wherein
the reference value is set based on whether pixel repair has been performed.

19. The electronic apparatus of claim 15, wherein
the sensing driver and the data driver are configured to be integrated.

20. The electronic apparatus of claim 15, wherein
the sensing driver is configured to detect a change in a current of the at least one dummy pixel line, wherein the change in a current is caused by creating a current path between at least one of the plurality of repair lines and one of the plurality of data lines.
